(19) United States
(12) Patent Application Publication
(10) Pub. No.: US 2013/0341774 A1
(43) Pub. Date: Dec. 26, 2013

(54) SEMICONDUCTOR PACKAGE AND METHOD OF FABRICATING THE SAME

(71) Applicant: SILICONWARE PRECISION INDUSTRIES CO., LTD., Taichung (TW)

(72) Inventors: Chiang-Cheng Chang, Taichung (TW); Meng-Tsung Lee, Taichung (TW); Shih-Kuang Chiu, Taichung (TW)

(73) Assignee: Siliconware Precision Industries Co., Ltd., Taichung (TW)

(21) Appl. No.: 13/628,795

(22) Filed: Sep. 27, 2012

(30) Foreign Application Priority Data
Jun. 22, 2012 (TW) 101122365

(51) Int. Cl. H01L 23/495; H01L 21/56

(52) U.S. Cl. 257/666; 438/123; 257/E23.031; 257/E21.502

(57) ABSTRACT

A semiconductor package is provided, including: an insulating layer; a semiconductor element embedded in the insulating layer; an adhesive body embedded in the insulating layer, wherein a portion of the semiconductor element is embedded in the adhesive body; a patterned metal layer embedded in the adhesive body and electrically connected to the semiconductor element; and a redistribution structure formed on the insulating layer and electrically connected to the patterned metal layer. By embedding the semiconductor element in the adhesive body, the present invention can securely fix the semiconductor element at a predetermined position without any positional deviation, thereby improving the product yield.

### BACKGROUND OF THE INVENTION

1. Field of the Invention

The present invention relates to semiconductor packages and methods of fabricating the same, and, more particularly, to a wafer level semiconductor package and a method of fabricating the same.

2. Description of Related Art

Along with the rapid development of electronic industries, electronic products are developed to have a variety of functionalities and high electrical performance. Wafer level packaging (WLP) technologies have been developed to meet the miniaturization requirement of semiconductor packages.

FIGS. 1A to 1D are schematic cross-sectional views showing a method of fabricating a wafer level semiconductor package 1 as disclosed by U.S. Pat. No. 6,452,265 and No. 7,202,107.

Referring to FIG. 1A, a thermal release tape 100 is formed on a carrier 10, and a plurality of semiconductor chips 12 are disposed on the thermal release tape 100. Each of the semiconductor chips 12 has an active surface 12a with a plurality of electrode pads 120 and an inactive surface 12b opposite to the active surface 12a, and is disposed on the thermal release tape 10 via the active surface 12a.

Referring to FIG. 1B, an encapsulant 13 that encapsulates the semiconductor chips 12 is formed on the thermal release tape 100 by molding.

Referring to FIG. 1C, a curing process is performed to cure the encapsulant 13. Meanwhile, the thermal release tape 100 loses its adhesive property during the curing process. As such, the thermal release tape 100 and the carrier 10 can be removed to expose the active surfaces 12a of the semiconductor chips 12.

Referring to FIG. 1D, a redistribution structure 14 is formed on the encapsulant 13 and the active surfaces 12a of the semiconductor chips 12 and electrically connecting the electrode pads 120 of the semiconductor chips 12.

Then, an insulating layer 15 is formed on the redistribution structure 14, and a plurality of openings are formed in the insulating layer 15 such that a portion of the redistribution structure 14 is exposed for solder balls 16 to be mounted thereon.

However, the thermal release tape 100 is flexible. During a molding process, the coefficient of thermal expansion (CTE) of the thermal release tape 100 and lateral forces from the encapsulant 13 can likely cause positional deviation of the semiconductor chips 12 (that is, positions of the semiconductor chips 12 are deviated from a chip areas B), as shown in FIG. 1D′, thereby adversely affecting the positional accuracy of the semiconductor chips 12. The larger the size of the carrier 10 is, the more severe the positional deviation of the semiconductor chips 12 becomes. As such, the electrical connection between the redistribution structure 14 and the semiconductor chips 12 is adversely affected, and consequently the product yield is reduced. Further, after the carrier 10 is removed, the encapsulant 13 may suffer from a serious warpage.

Therefore, there is a need to provide a semiconductor package and a method of fabricating the same so as to overcome the above-described drawbacks.

### SUMMARY OF THE INVENTION

In view of the above-described drawbacks, the present invention provides a semiconductor package, which comprises: a first insulating layer having opposite first and second surfaces; a semiconductor element embedded in the first insulating layer; an adhesive body embedded in the first insulating layer and having a surface exposed from the first surface of the first insulating layer, a portion of the semiconductor element being embedded in the adhesive body; a patterned metal layer embedded in the adhesive body and electrically connected to the semiconductor element and having a surface exposed from the first surface of the first insulating layer; and a redistribution structure formed on the first surface of the first insulating layer, the patterned metal layer and the adhesive body and electrically connected to the patterned metal layer.

In an embodiment, the first surface of the first insulating layer has a protruding portion so as for the patterned metal layer and the adhesive body to be embedded therein.

In an embodiment, the semiconductor element has an active surface and an inactive surface opposite to the active surface, and the active surface and a portion of side surfaces of the semiconductor element are embedded in the adhesive body and electrically connected to the patterned metal layer.

The present invention further provides a method of fabricating a semiconductor package, which comprises the steps of: providing a carrier having a patterned metal layer; forming on the carrier at least an adhesive body encapsulating the patterned metal layer; disposing a semiconductor element on the adhesive body, wherein a portion of the semiconductor element is embedded in the adhesive body and electrically connected to the patterned metal layer; forming on the carrier a first insulating layer encapsulating the semiconductor element and the adhesive body, wherein the first insulating layer has a first surface and a second surface opposite to the first surface and the first surface of the first insulating layer is bonded to the carrier; removing the carrier to expose the first surface of the first insulating layer, the patterned metal layer and the adhesive body; and forming on the first surface of the first insulating layer, the patterned metal layer and the adhesive body a redistribution structure electrically connected to the patterned metal layer.

In an embodiment, a release layer is further formed on the carrier in a manner that the patterned metal layer and the adhesive body are formed on the release layer, thereby facilitating to remove the carrier.

In an embodiment, a groove is further formed on the carrier and the semiconductor element is disposed in the groove.

In an embodiment, the first insulating layer is formed by laminating or coating.

In an embodiment, the carrier is removed by grinding.

In an embodiment, the patterned metal layer further comprises a plurality of conductive pads electrically connected to the semiconductor element.

In an embodiment, the adhesive body is made of a non-liquid adhesive material.

In an embodiment, the semiconductor element has an active surface and an inactive surface opposite to the active surface, and the active surface has a plurality of conductive bumps embedded in the adhesive body and electrically connected to the patterned metal layer.

In an embodiment, the semiconductor element has an active surface and an inactive surface opposite to the active surface and exposed from the second surface of the first insulating layer.

In an embodiment, the redistribution structure comprises at least a dielectric layer, a circuit layer formed on the dielectric layer, and a plurality of conductive vias formed in the dielectric layer and electrically connected to the circuit layer and the patterned metal layer.

In an embodiment, a second insulating layer is further formed on the redistribution structure and have a plurality of openings that expose a portion of the redistribution structure.

Therefore, by embedding the semiconductor element in the adhesive body, the present invention can securely fix the semiconductor element at a predetermined position so as to prevent positional deviation from occurring to the semiconductor element during formation of the first insulating layer. Consequently, during formation of the redistribution structure, an effective electrical connection is implemented between the conductive vias and the semiconductor element, thereby improving the product yield.

Further, the present invention dispenses with the conventional thermal release tape so as to prevent serious warpage from occurring to the first insulating layer when the first insulating layer is cured.

### BRIEF DESCRIPTION OF DRAWINGS

FIGS. 1A to 1D are schematic cross-sectional views showing a method of fabricating a semiconductor package according to the prior art, wherein FIG. 1D′ is an upper view of FIG. 1C;

FIGS. 2A to 2F are schematic cross-sectional views showing a method of fabricating a semiconductor package according to a first embodiment of the present invention, wherein FIG. 2A′ shows another embodiment of FIG. 2A, and FIGS. 2F′ and 2F″ show different embodiments of FIG. 2F; and

FIGS. 3A to 3C are schematic cross-sectional views showing a method of fabricating a semiconductor package according to a second embodiment of the present invention.

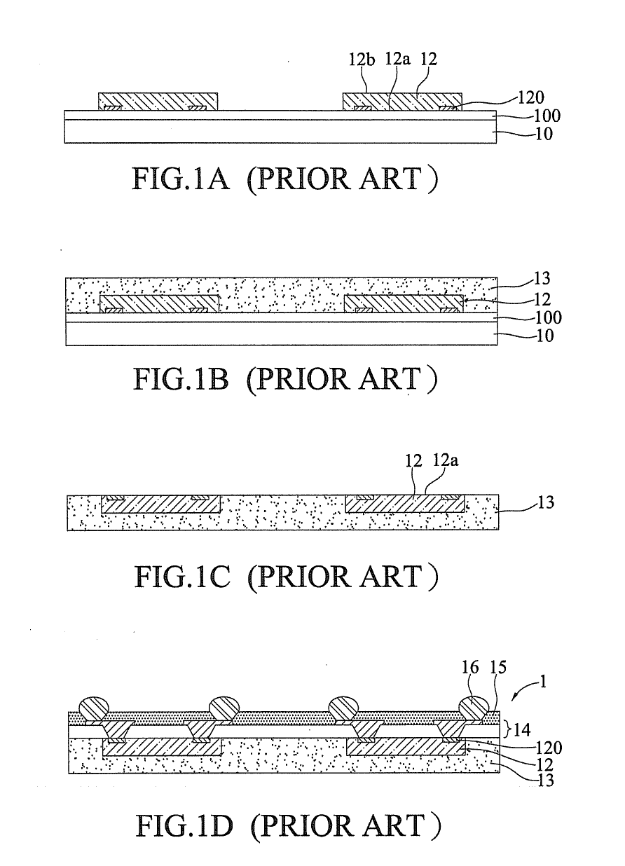

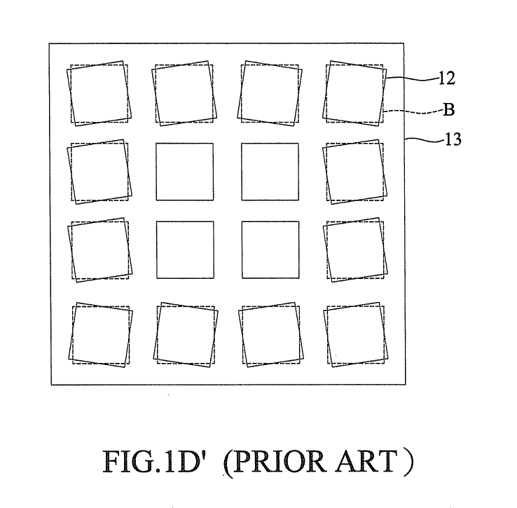

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modification and variations can be made without departing from the spirit of the present invention. Further, terms such as “first”, “second”, “on”, “a” etc. are merely for illustrative purpose and should not be construed to limit the scope of the present invention.

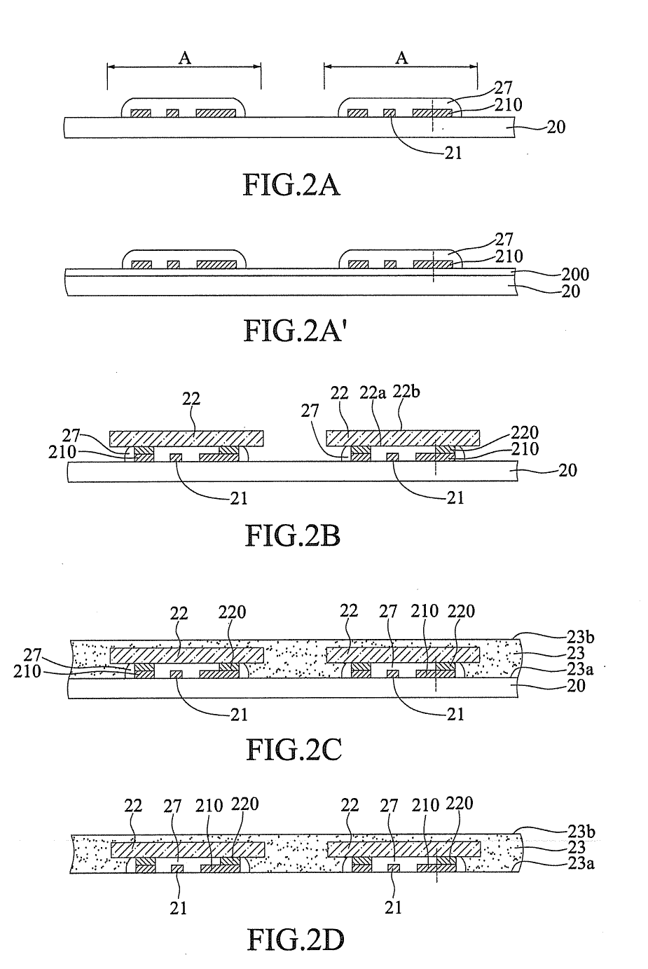

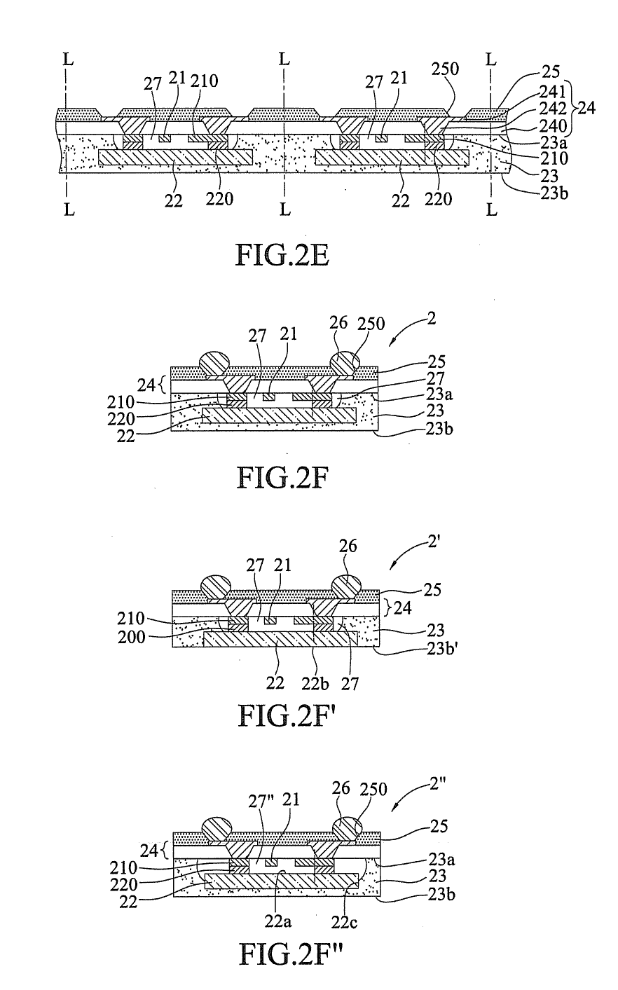

FIGS. 2A to 2F are schematic cross-sectional views showing a semiconductor package 2 and a method of fabricating the same according to a first embodiment of the present invention.

Referring to FIG. 2A, a patterned metal layer 21 is formed on a carrier 20 and then a plurality of adhesive bodies 27 are formed on the carrier 20 to encapsulate the patterned metal layer 21. The adhesive bodies 27 securely fix a plurality of semiconductor elements 22 at predetermined positions.

In an embodiment, a plurality of chip areas A are defined on the carrier 20 such that the adhesive bodies 27 are formed correspondingly in position to the chips areas A.

Further, the patterned metal layer 21 can have a plurality of conductive pads 210. The adhesive bodies 27 can be made of a non-liquid adhesive material.

In an embodiment, referring to FIG. 2A′, a release layer 200 is formed on the carrier 20 in a manner that the patterned metal layer 21 and the adhesive bodies 27 are formed on the release layer 200. The release layer 200 can be made of polymer and formed on the carrier 20 by sputtering or coating.

In an embodiment, the release layer 200 can be made of a material having a low CTE so as to avoid positional deviation of semiconductor elements 22. Preferably, the release layer 200 is made of a material having a CIE lower than 10.

Referring to FIG. 2B, a plurality of semiconductor elements 22 are disposed on the adhesive bodies 27, such that each of the chip areas A has a corresponding one of the semiconductor elements 22 disposed therein. Each of the semiconductor elements 22 has a plurality of conductive bumps 220 embedded in the corresponding adhesive body 27 for electrically connecting to the conductive pads 210.

In an embodiment, the semiconductor elements 22 are chips, and each of the semiconductor elements 22 has an active surface 22a with a plurality of electrode pads (not shown) and an inactive surface 22b opposite to the active surface 22a. The conductive bumps 220 are formed on the electrode pads.

The semiconductor elements 22 are embedded in the adhesive bodies 27 by laminating.

The conductive bumps 220 are made of a solder material such as an Sn—Ag lead-free solder material. The solder material can further contain Cu, Ni, Ge and so on. Therefore, the semiconductor elements 22 can be soldered to the conductive pads 210 so as to securely fix the semiconductor elements 22.

In an embodiments, a tin layer (not shown) is formed to cover the conductive pads 210 so as to serve as a surface treatment layer. The tin layer is directly bonded with the electrode pads of the semiconductor elements 22, without the need of the conductive bumps 220.

Further, after the semiconductor elements 22 are disposed on the adhesive bodies, a curing process can be selectively performed so as to cure the adhesive bodies 27.

Referring to FIG. 2C, a first insulating layer 23 is formed on the carrier 20 so as to embed the semiconductor elements 22 and the adhesive bodies 27 in the first insulating layer 23. The first insulating layer 23 has a first surface 23a and a second surface 23b opposite to the first surface 23a, and the first surface 23a of the first insulating layer 23 is bonded to the carrier 20.

In an embodiment, the first insulating layer 23 is made of a dry film and formed on the carrier 20 by laminating.

Alternatively, the first insulating layer 23 can be made of polyimide (PI). In an embodiment, the first insulating layer 23 can be formed by coating.

Referring to FIG. 2D, the carrier 20 is removed by grinding so as to expose the first surface 23a of the first insulating layer 23, the patterned metal layer 21 and the adhesive bodies 27.

In an embodiment, referring to FIG. 2A′, the carrier 20 can be easily removed through the release layer 200.

Referring to FIG. 2E, an RDL process is performed such that a redistribution structure 24 is formed on the first surface 23a of the first insulating layer 23, the patterned metal layer 21 and the adhesive bodies 27 and electrically connected to the conductive pads 210.

In an embodiment, the redistribution structure 24 has at least a dielectric layer 240, a circuit layer 241 formed on the dielectric layer 240, and a plurality of conductive vias 242 formed in the dielectric layer 241 and electrically connected to the circuit layer 241 and the conductive pads 210. The dielectric layer 240 can be made of polyimide (PI), benezocyclobutene (BCB) or polybenzoxazole (PBO).

Further, a second insulating layer 25 is formed on the dielectric layer 240 and a plurality of openings 250 are formed in the second insulating layer 25 to expose a portion of the circuit layer 241.

Referring to FIG. 2F, a singulation process is performed along cutting lines L of FIG. 2E so as to obtain a plurality of semiconductor packages 2. Conductive elements such as solder balls 26 are further formed on the exposed portion of the circuit layer 241.

Referring to FIG. 2F′, in an embodiment, when the first insulating layer 23 is formed, the inactive surfaces 22b of the semiconductor elements 22 are exposed from the second surface 23b′ of the first insulating layer 23 for dissipating heat or allowing a heat dissipating structure to be mounted thereon. Alternatively, the second surface 23b′ of the first insulating layer 23 can be ground to expose the inactive surfaces 22b of the semiconductor elements 22.

Referring to FIG. 2F″, in an, large-sized adhesive bodies 27′ are formed in the process of FIG. 2A such that the active surface 22a and a portion of side surfaces 22c of each of the semiconductor elements 22 are embedded in the corresponding adhesive body 27′ and electrically connected the patterned metal layer 21.

According to the method of fabricating the semiconductor package 2, the semiconductor elements 22 are embedded in the adhesive bodies 27 so as to be securely fixed at predetermined positions. Therefore, the present invention prevents positional deviation from occurring to the semiconductor elements 22 during formation of the first insulating layer 23. Even if the size of the carrier 29 increases, the positional deviation of the semiconductor elements 22 does not increase, thereby improving the positional accuracy of the semiconductor elements 22. Further, during formation of the redistribution structure 24, an effective electrical connection can be implemented between the semiconductor elements 22 and the conductive vias 242 so as to increase the product yield.

Furthermore, the present invention dispenses with the conventional thermal release tape so as to prevent serious warpage from occurring to the first insulating layer 23 when the first insulating layer 23 is cured.

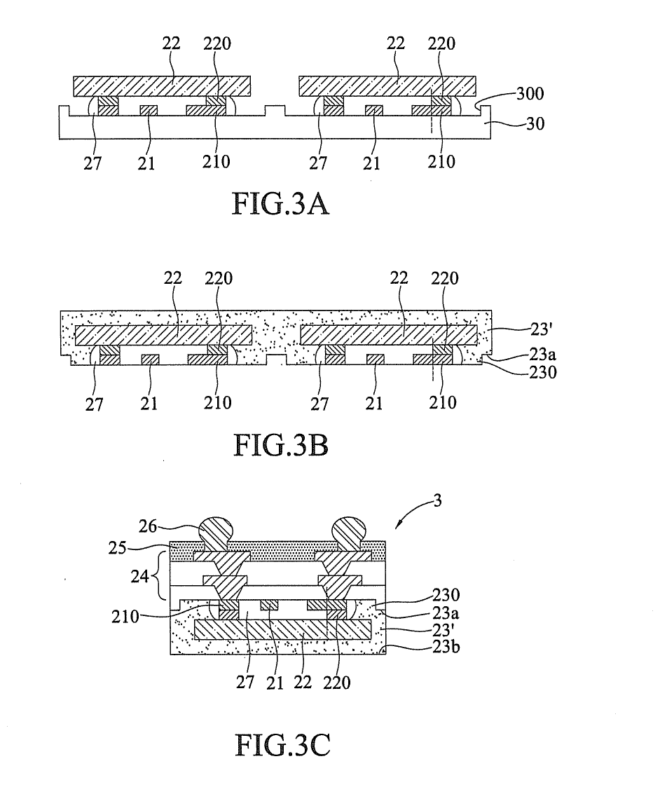

FIGS. 3A to 3C are schematic cross-sectional views showing a method of fabricating a semiconductor package 3 according to a second embodiment of the present invention. The second embodiment differs from the first embodiment in the structure of the carrier 30.

Referring to FIG. 3A, a plurality of grooves 300 are formed on the carrier 30 so as for the semiconductor elements 22 to be received therein, thereby improving the alignment accuracy of the semiconductor elements 22 on the carrier 30.

In an embodiment, the semiconductor elements 22 are bonded to the carrier 30 through the adhesive bodies 27 in the grooves 300, and the patterned metal layer 21 is formed on bottom surfaces of the grooves 300 for connecting the electrode pads (not shown) or the conductive bumps 220 of the semiconductor elements 22.

Referring to FIG. 3B, a molding process is performed and the carrier 30 is removed such that a plurality of protruding portions 230 are formed on the first surface 23a of the first insulating layer 23′. The patterned metal layer 21 and the adhesive bodies 27 are located in the protruding portions 230.

Referring to FIG. 3C, an RDL process and a singulation process are performed to obtain a plurality of semiconductor packages 3.

The present invention further provides a semiconductor package 2, 2′, 2″, 3, which has: a first insulating layer 23 having opposite first and second surfaces 23a, 23b; a semiconductor element 22 embedded in the first insulating layer 23, wherein the semiconductor element 22 has an active surface 22a with a plurality of conductive bumps 220 and an inactive surface 22b opposite to the active surface 22a; an adhesive body 27 embedded in the first insulating layer 23 and encapsulating the conductive bumps 220 and having a surface exposed from the first surface 23a of the first insulating layer 23; a patterned metal layer 21 embedded in the adhesive body 27 and having a plurality of conductive pads 210 electrically connected to the conductive bumps 220 of the semiconductor element 22 and having a surface exposed from the first surface 23a of the first insulating layer 23; and a redistribution structure 24 formed on the first surface 23a of the first insulating layer 23, the patterned metal layer 21 and the adhesive body 27 and electrically connected to the patterned metal layer 21.

The inactive surface 22b of the semiconductor element 22 can be selectively exposed from the second surface 23b′ of the first insulating layer 23. The conductive bumps 220 can be made of a solder material.

The adhesive body 27 can be made of a non-liquid adhesive material.

The patterned metal layer 21 can be made of copper.

The redistribution structure 24 has at least a dielectric layer 240, a circuit layer 241 formed on the dielectric layer 240 and a plurality of conductive vias 242 formed in the dielectric layer 240 and electrically connected to the circuit layer 241 and the patterned metal layer 21.

Further, a second insulating layer 25 can be formed on the outermost dielectric layer 240 and have a plurality of openings for exposing a portion of the circuit layer 241.

In an embodiment, the first surface 23a of the first insulating layer 23′ has a protruding portion 230 so as for the patterned metal layer 21 and the adhesive body 27 to be embedded therein.

In an embodiment, the active surface 22a and a portion of the side surfaces 22c of the semiconductor element 22 are embedded in the adhesive body 27′ and electrically connected to the patterned metal layer 21.

Therefore, by embedding the semiconductor element in the adhesive body, the present invention can securely fix the semiconductor element at a predetermined position so as to prevent positional deviation from occurring to the semiconductor element. Consequently, an effective electrical connection can be implemented between the conductive vias and the semiconductor element so as to improve the product yield.

Further, the present invention dispenses with the conventional thermal release tape so as to prevent serious warpage from occurring to the first insulating layer.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A semiconductor package, comprising:
a first insulating layer having opposite first and second surfaces;
a semiconductor element embedded in the first insulating layer;
an adhesive body embedded in the first insulating layer and having a surface exposed from the first surface of the first insulating layer, a portion of the semiconductor element being embedded in the adhesive body;
a patterned metal layer embedded in the adhesive body and electrically connected to the semiconductor element, the patterned metal layer having a surface exposed from the first surface of the first insulating layer; and
a redistribution structure formed on the first surface of the first insulating layer, the patterned metal layer and the adhesive body and electrically connected to the patterned metal layer.

2. The semiconductor package of claim 1, wherein the first surface of the first insulating layer has a protruding portion, and the patterned metal layer and the adhesive body are embedded in the protruding portion.

3. The semiconductor package of claim 1, wherein the patterned metal layer further comprises a plurality of conductive pads electrically connected to the semiconductor element.

4. The semiconductor package of claim 1, wherein the adhesive body is made of a non-liquid adhesive material.

5. The semiconductor package of claim 1, wherein the semiconductor element has an active surface and an inactive surface opposite to the active surface, the active surface and a portion of side surfaces of the semiconductor element being embedded in the adhesive body and electrically connected the patterned metal layer.

6. The semiconductor package of claim 1, wherein the semiconductor element has an active surface and a plurality of conductive bumps disposed on the active surface, embedded in the adhesive body and electrically connected to the patterned metal layer.

7. The semiconductor package of claim 1, wherein the semiconductor element has an active surface and an inactive surface opposite to the active surface and exposed from the second surface of the first insulating layer.

8. The semiconductor package of claim 1, wherein the redistribution structure comprises at least a dielectric layer, a circuit layer formed on the dielectric layer, and a plurality of conductive vias formed in the dielectric layer and electrically connected to the circuit layer and the patterned metal layer.

9. The semiconductor package of claim 1, further comprising a second insulating layer formed on the redistribution structure and having a plurality of openings that expose a portion of the redistribution structure.

10. A method of fabricating a semiconductor package, comprising:
providing a carrier having a patterned metal layer;
forming on the carrier at least an adhesive body encapsulating the patterned metal layer;
disposing on the adhesive body a semiconductor element, which is partially embedded in the adhesive body and electrically connected to the patterned metal layer;
forming on the carrier a first insulating layer for encapsulating the semiconductor element and the adhesive body, wherein the first insulating layer has a first surface and a second surface opposite to the first surface and the first surface of the first insulating layer is bonded to the carrier;
removing the carrier to expose the first surface of the first insulating layer, the patterned metal layer and the adhesive body; and
forming on the first surface of the first insulating layer, the patterned metal layer and the adhesive body a redistribution structure electrically connected to the patterned metal layer.

11. The method of claim 10, further comprising forming a release layer on the carrier in a manner that the patterned metal layer and the adhesive body are formed on the release layer.

12. The method of claim 10, further comprising forming on the carrier a groove, wherein the semiconductor element is disposed in the groove.

13. The method of claim 10, wherein the patterned metal layer further comprises a plurality of conductive pads electrically connected to the semiconductor element.

14. The method of claim 10, wherein the adhesive body is made of a non-liquid adhesive material.

15. The method of claim 10, wherein the semiconductor element has an active surface and an inactive surface opposite to the active surface, the active surface having a plurality of conductive bumps embedded in the adhesive body and electrically connected to the patterned metal layer.

16. The method of claim 10, wherein the semiconductor element has an active surface and an inactive surface opposite to the active surface and exposed from the second surface of the first insulating layer.

17. The method of claim 10, wherein the first insulating layer is formed by laminating or coating.

18. The method of claim 10, wherein the carrier is removed by grinding.

19. The method of claim 10, wherein the redistribution structure comprises at least a dielectric layer, a circuit layer formed on the dielectric layer, and a plurality of conductive vias formed in the dielectric layer and electrically connected to the circuit layer and the patterned metal layer.

20. The method of claim 10, further comprising forming on the redistribution structure a second insulating layer having a plurality of openings that exposes a portion of the redistribution structure.
